(19) United States
(12) Patent Application Publication
(10) Pub. No.: US 2008/0203567 A1
(43) Pub. Date: Aug. 28, 2008

(54) SEMICONDUCTOR PACKAGE AND SEMICONDUCTOR DEVICE USING THE SAME

(75) Inventor: Takeshi Kondo, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/032,038

(22) Filed: Feb. 15, 2008

(30) Foreign Application Priority Data
Feb. 22, 2007 (JP) 2007-041720

(51) Int. Cl. H01L 23/52

(52) U.S. Cl. 257/738; 257/E23.141

(57) ABSTRACT

A semiconductor package includes a print substrate which has a plurality of wiring layers. The print substrate has a wiring for connect pins extending internally across the plurality of wiring layers from one surface of the print substrate; a wiring for a non connect pin insulated in the thickness direction of the plurality of wiring layers by a void formed to an intermediate wiring layer as one of the plurality of wiring layers; and a surge absorption wiring facing the wiring for the non connect pin across the void. The interval of the void between the wiring for the non connect pin and the surge absorption wiring is set smaller than the interval between a non connect pin to be disposed and a connect pin adjacent to the connect pin.

This application is based upon and claims the benefit of priority from Japanese patent application No. 2007-041720 filed on Feb. 22, 2007, the disclosure of which is incorporated herein in its entirety by reference.

### BACKGROUND OF THE INVENTION

1. Field of the Invention

The present invention relates to a semiconductor package and a semiconductor device using the same, and more particularly, to suppression of an electrostatic discharge (ESD) from a non connection terminal placed in a floating state to a connection terminal placed in an active state.

2. Description of the Related Art

Reduction in size of semiconductor devices has been proceeding every year. The size of semiconductor chips is reduced by the development of a micromachining technology, and semiconductor packages are also reduced in size by employing BGA (Ball Grid Array) and CSP (Chip Size Package). Solder balls are used to these small semiconductor packages as outside terminals (pins). A BGA package is a surface mounted type package arranged such that semiconductor chips are mounted on one surface of a print substrate and solder balls are disposed on the other surface of the print substrate in a grid-shape. Semiconductor packages having a narrow pitch between pins can be obtained by disposing the solder balls in the grid-shape as outside terminals (pins).

A semiconductor package with a narrow pitch between pins, which is typically represented by the BGA package, has a non connect pin (hereinafter, called an NC pin) which is not connected to any portion of the semiconductor chip. When ESD noise is applied to the NC pin, it performs an aerial discharge to an adjacent input/output pin because no discharging path is disposed. As a result, the semiconductor chip is broken by the ESD noise transmitted to the input/output pin. The breakdown of the semiconductor chip caused by the electrostatic charge is called ESD breakdown (ESD Breakdown). A countermeasure against the ESD is necessary to semiconductor devices.

To solve the problem, Japanese Unexamined Patent Application Publication No. 2002-198466, for example, discloses two types of semiconductor packages. FIGS. 6A and 6B show one type of them, and FIG. 6A is a plan view and FIG. 6B is a sectional view taken along a line A-A of FIG. 6A. In a package, a solder ball 2 as an NC pin P1 and solder balls 2 as input/output pins P3 are disposed in a print substrate 1, and conducting wirings 3 are exposed in air between the NC pin 1 and the input/output pins P3. The conducting wirings 3 are disposed in the vicinity of the NC pin P1 and connected to a ground potential (pin P2). It is intended in this arrangement to absorb a surge due to the aerial discharge (shown by an arrow in the drawing) from the NC pin P1, to which the ESD noise is applied, by the conducting wiring 3.

FIGS. 7A and 7B show another package, and FIG. 7A is a plan view and FIG. 7B is a sectional view taken along a line C-C of FIG. 7A. In the package, a conductive wiring 15 is disposed around a solder ball 2 as an NC pin P1 on the entire upper surface of a print substrate 1 to absorb a surge. Accordingly, insulation films 13 are formed to surround the peripheries of the solder balls 2 to prevent short circuit between the solder ball 2 as the NC pin P1 and solder balls 2 as other pins in the print substrate 1.

Further, Japanese Unexamined Patent Application Publication No. 2005-317759 discloses a technology for protecting a semiconductor device from an excessive voltage due to a surge voltage and static electricity by adding capacitance patterns confronting a ground wiring, disposing projecting patterns between signal wirings and the capacitance patterns, and discharging the excessive voltage between the projecting patterns.

### SUMMARY OF THE INVENTION

The package disclosed in Japanese Unexamined Patent Application Publication No. 2005-317759 entails the following problem which is arisen by exposing the conducting wiring 3, which absorbs the surge, or the conductive wirings 15 exposed on the surface of the substrate 1.

(1) There is a possibility that the diselectrification capability of the conducting wirings 3 or the conductive wirings 15 are deteriorated because the surfaces of them are corroded and oxidized by moistures, dusts, and the like in the atmosphere.

(2) There is a possibility that the solder balls 2 may be cracked because the insulation films 13 surrounding the peripheries of the solder balls 2 apply heat stress and mechanical stress to them from the edges thereof. Japanese Unexamined Patent Application Publication No. 2005-317759 does disclose ESD caused by a non connect pin.

In view of the above problems, the present invention provides a semiconductor package having a novel structure capable of suppressing electrostatic discharge (EDS) from a non connect terminal to a connect terminal and a semiconductor device using the same.

According to a first aspect of the present invention, a semiconductor package can be obtained which has a print substrate composed of a plurality of wiring layers, wherein the semiconductor package includes a void formed to an intermediate wiring layer which is one of the plurality of wiring layers, and the wiring of a non connect pin and a noise absorption wiring are disposed to face to each other across the void.

It is preferable that the void interval (D) between the wiring of the non connect pin and the noise absorption wiring, which face to each other, be shorter than the interval (L) between pins to be connected to the outside.

According to a second aspect of the present invention, a semiconductor device is provided which has a semiconductor package which is composed of a print substrate including a plurality of wiring layers including an intermediate wiring layer, a void disposed to the intermediate wiring layer, and a wiring of a non connect pin and a noise absorption wiring disposed to face to each other across the void; solder balls mounted on a first side surface of the print substrate; and the semiconductor chip mounted on a second side surface facing the first side surface.

According to a third aspect of the present invention, a semiconductor package is obtained which has a print substrate composed of a plurality of wiring layers, wherein the semiconductor package is composed of a wiring for connect pins extending internally across the plurality of wiring layers from one surface of the print substrate, a wiring for a non connect pin insulated in the thickness direction of the plurality of wiring layers by a void formed to an intermediate wiring layer as one of the plurality of wiring layers, and a surge absorption wiring facing the wiring for the non connect pin across the void.

The interval of the void between the wiring for the non connect pin and the surge absorption wiring may be set smaller than the interval between a non connect pin to be disposed and a connect pin adjacent to the connect pin. The surge absorption wiring may be connected to at least one of the ground potential wiring or the power supply potential wiring.

According to a further aspect of the present invention, there can be obtained a semiconductor device which is composed of a semiconductor package including a print substrate comprising a plurality of wiring layers, wiring for connect pins extending internally across the plurality of wiring layers from one surface of the print substrate, a wiring for a non connect pin insulated in the thickness direction of the plurality of wiring layers by a void formed to an intermediate wiring layer as one of the plurality of wiring layers, and a surge absorption wiring facing the wiring for the non connect pin across the void, and a plurality of pins including the connect pin and the non connect pin disposed to one surface of the print substrate and a semiconductor chip mounted on the other surface, wherein the connect pin is connected to the semiconductor chip and the surge absorption wiring is connected to at least one of the ground potential wiring or the power supply potential wiring.

In the semiconductor package of the present invention, the void is disposed to the intermediate wiring layer in the plurality of wirings layers, and the wiring of the non connect pin and the noise absorption wiring are disposed to the upper and lower wiring layers across the void so that they face to each other. The void interval (D) is shorter than the interval (L) between the pins (solder balls), and the noise absorption wiring is connected to the ground electric potential wiring or to the power supply potential wiring. With this structure, ESD noise can be absorbed by the noise absorption wiring. The void between the wiring of the NC pin and the surge absorption conductive wiring is disposed in the wiring layer of the print substrate so that the surge absorption conductive wiring is not exposed. With this structure, there can be obtained an effect of preventing deterioration of a diselectrification capability which is caused by the corrosion and the oxidation of the surge absorption conductive wiring when it is exposed to the surface of the substrate.

### BRIEF DESCRIPTION OF THE DRAWINGS

FIG. 1 is a plan view of a semiconductor package of a first exemplary embodiment on a solder ball side;

FIG. 2 is a sectional view taken along a line X-X of FIG. 1;

FIGS. 3A and 3B are plan views of the respective layers of the semiconductor package, wherein FIG. 3A shows an insulation layer and FIG. 3B shows a first wiring layer;

FIGS. 4A and 4B are plan views of the respective layers of the semiconductor package, wherein FIG. 4A shows a second wiring layer and FIG. 4B shows a third wiring layer;

FIG. 5 is a plan view of a third wiring layer of a semiconductor package in a second exemplary embodiment;

FIG. 6A is a plan view of a first semiconductor package of a conventional example and FIG. 6B is a sectional view thereof; and

FIG. 7A is a plan view of a second semiconductor package of the conventional example and FIG. 7B is a sectional view thereof.

### DESCRIPTION OF THE EXEMPLARY EMBODIMENTS

A semiconductor package of the present invention will be explained below in detail referring to the drawings.

### First Exemplary Embodiment

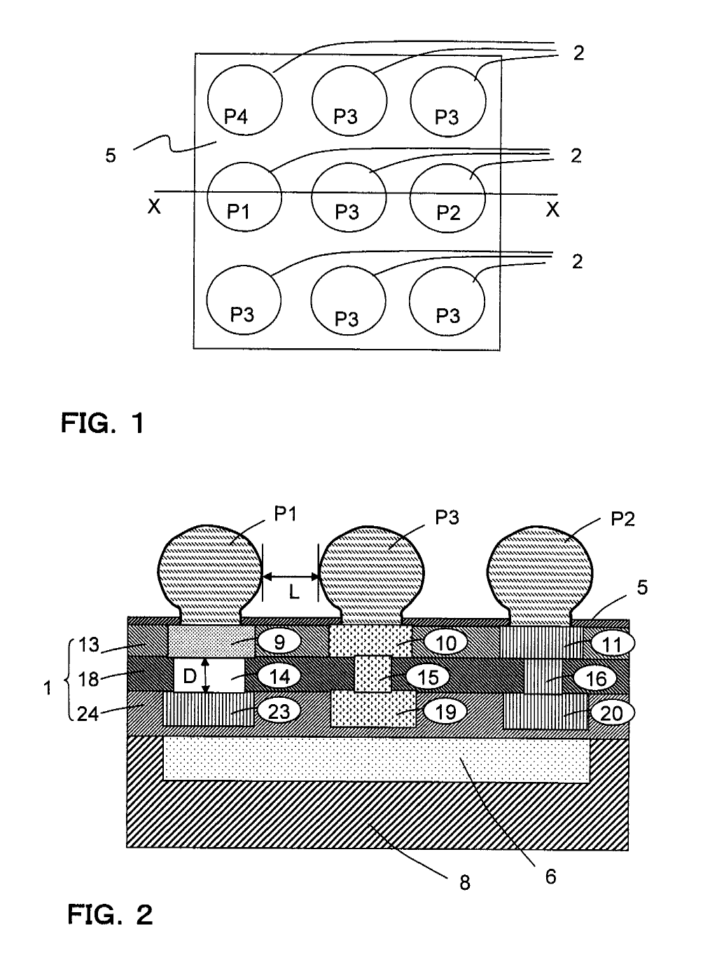

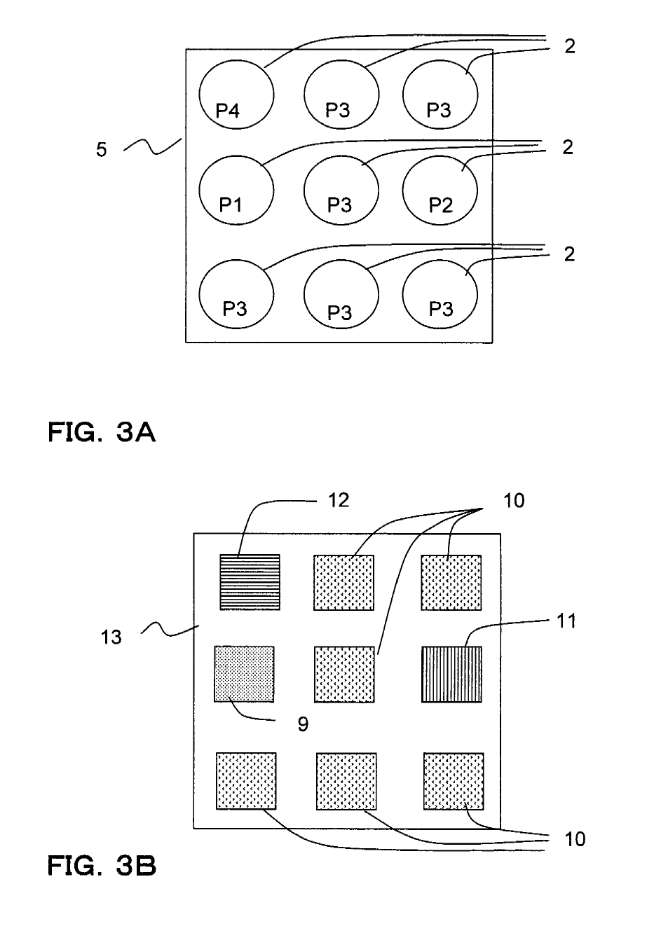

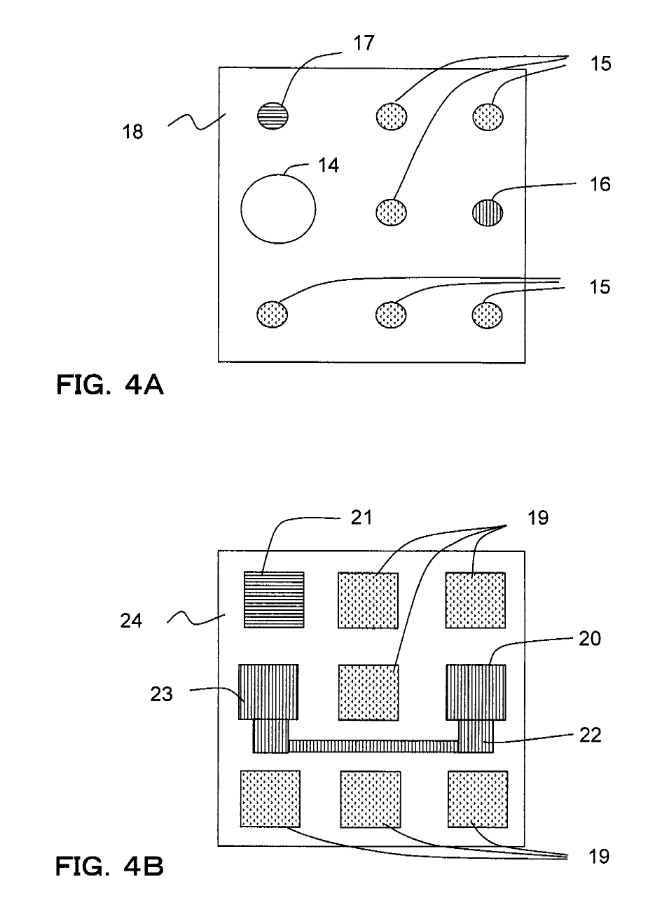

A first exemplary embodiment of the present invention will be explained in detail referring to FIGS. 1 to 4B. FIG. 1 shows a plan view of a pattern of a semiconductor package in the embodiment on a solder ball side, and FIG. 2 shows a sectional view of the semiconductor package taken along a line X-X of FIG. 1. FIGS. 3A, 3B, 4A, and 4B are plan views of patterns in the respective layers of the semiconductor package and show an insulation layer, a first wiring layer (FIG. 3B), a second wiring layer (FIG. 4C), and a third wiring layer, respectively.

Referring to FIGS. 1 and 2, a print substrate 1 of the semiconductor package is composed of three wiring layers of first, second, and third wiring layers 13, 18, and 24. An insulation film layer 5 is formed on the upper surface of the first wiring layer 13. A semiconductor chip 6 is mounted on the third wiring layer 24, electrically connected by a wiring and the like (not shown), and covered with a sealing resin 8 on the front surface side of the semiconductor package (on the lower side in the drawing). Solder balls 2 are mounted to the respective wirings (lands) of the first wiring layer 13 and the potions between the solder balls are insulated by the insulation film layer 5 on the back surface side of the semiconductor package (on the upper side in the drawing). In the drawings, nine pieces of the solder balls 2 are disposed, and, for example, the respective solder balls 2 are an NC pin P1, a ground potential pin P2, input/output pins P3, and a power supply potential pin P4.

In FIG. 2, the solder ball 2 as the NC pin P1 is connected to a wiring (land) 9 of the first wiring layer 13. In the second wiring layer 18, a through hole (void) 14 is located under the land 9, and the NC pin PI is not connected to the semiconductor chip. Further, a wiring 23 of the third wiring layer 24 under the second wiring layer 18 is disposed in confrontation with the wiring 9 of the first wiring layer 13 and connected to a ground potential.

The solder balls 2 as the input/output pins P3 are connected to a wiring (land) 10 of the first wiring layer 13, to a wiring 15 of the second wiring layer 18 under the first wiring layer 13, and further to a wiring 19 of the third wiring layer 24 under the second wiring layer 18. The wiring 19 is electrically connected to a pad of the semiconductor chip 6 through a wire and the like (not shown). The solder ball 2 as the ground potential pin P2 is connected to a wiring (land) 11 of the first wiring layer 13, to a wiring 16 of the second wiring layer 18 under the first wiring layer 13, and further to a wiring 20 of the third wiring layer 24 under the second wiring layer. The wiring 20 is electrically connected to the pad of the semiconductor chip 6 through a wire and the like (not shown).

The plan views of the patterns of the insulation film layer 5 and the wiring layers 13, 18, 24, which constitute the print substrate 1, will be explained referring to FIGS. 3A, 3B, 4A, and 4B, respectively. The insulation film layer 5 shown in FIG. 3A is composed of an insulation film, and holes are formed to the portions thereof where the solder balls 2 are mounted. The first wiring layer 13 shown in FIG. 3B has wirings (lands) disposed thereto so that solder balls are mounted thereon. The wiring 9 to be connected to the NC pin P1, the wiring 11 to be connected to 11 the ground potential pin P2, the wiring 10 to be connected to the input/output pins P3, and a wiring 12 to be connected to the power supply pin are arranged corresponding to the respective pins.

The second wiring layer 18 shown in FIG. 4A is an intermediate wiring layer for connecting the first wiring layer 13 to the third wiring layer 24. The intermediate wiring layer 18 is composed of the wiring 15 to be connected to the wiring 10, a wiring 16 to be connected to the wiring 11, a wiring 17 to be connected to the wiring 12, and the through hole (interval) 14 disposed so as to confront the wiring 9. No wiring is connected to the wiring 9, and the void 14 is formed in place of the wiring. The third wiring layer 24 shown in FIG. 4B includes the wiring 19 to be connected to the wiring 10 through the wiring 15, a wiring 20 to be connected to the wiring 11 through the wiring 16, and a wiring 21 to be connected to the wiring 12 through the wiring 17. Further, a wiring 22 for connecting the wiring 20 to the wiring 23 is disposed in the wiring layer 24. The wiring 23 of the third wiring layer 24 faces the wiring 9 of the first wiring layer 13 across the through hole 14 of the wiring layer 18.

The wirings 19, 20, and 21 in the third wiring layer 24 are electrically connected to the semiconductor chip 6, a wire (not shown) and the like. Although the solder ball of the NC pin P1 is mounted to the wiring 9, the second wiring layer has no wiring for connecting it. Accordingly, the NC pin P1 is neither connected to the wirings in the third wiring layer 24 nor connected to the semiconductor chip and is placed in an open state (or in a floating state). The wiring 23, which is connected to the ground potential facing the wiring 9 of the NC pin P1 across the void, acts as an ESD surge absorption wiring. The ESD surge absorption wiring is formed in the wiring layer 24 as described above and is not exposed. Here, in order to prevent an aerial discharge from the NC pin P1 to the adjacent input/output pins P3, the depth (interval) D of the through hole (void) 14 must be narrower than at least the interval L between the NC pin P1 and the input/output pins P3.

ESD noise applied to the NC pin of the semiconductor package will be explained. The ESD noise applied to the NC pin P1 electrostatically charges the solder balls and the wiring 9. At the time, since the depth D of the through hole 14 is shorter than the interval L between the adjacent pins, an aerial discharge is performed to the ground potential wiring 23. The ESD noise is aerially discharged to the ground potential wiring 23 nearest to the NC pin P1. The ESD noise is aerially discharged from the wiring 9 of the wiring layer 13 to the ground potential wiring 23 through the through hole 14 of the wiring layer 18, and a surge is absorbed to the wiring 20 set to the ground potential of the wiring layer 24. The ground potential wiring 23 is an ESD surge absorption wiring for absorbing the surge as described above.

Since the void interval D between the wiring of the NC pins and the ESD noise absorption wiring disposed in the package so as to face to each other is shorter than the interval L of the adjacent pins as described above, the aerial discharge is performed in the package. The surge is aerially discharged in the package and absorbed to the ESD surge absorption wiring 23 and the ground potential wiring 20. Since the ground potential wiring is commonly connected to the ground wiring in the semiconductor chip and has a large wiring capacity, it is not broken down and can absorb the ESD noise. Since the aerial discharge is performed to the ESD surge absorption wiring first, no aerial discharge is generated to the adjacent input/output pins P3.

In the semiconductor package of the embodiment, the wiring of the NC pin is disposed to face the ESD surge absorption wiring across the void having the interval D in the package. The interval D is made shorter than the interval L between the adjacent solder balls. With this arrangement, the ESD noise applied to the NC pin is aerially discharged to the ESD surge absorption wiring. Provision of the ESD noise absorption wiring can prevent transmission of a surge to the input/output pins. Since the ESD noise absorption wiring is disposed in the print substrate, when the solder ball is mounted, the adjacent pins can be prevented from being short circuited by a solder adhered to an exposed absorption wiring. Further, since the ESD noise absorption wiring is disposed in the print substrate, it can be prevented from being subjected to corrosion, oxidation, and the like which are caused when it were disposed in air, thereby the ESD noise being securely absorbed.

### Second Exemplary Embodiment

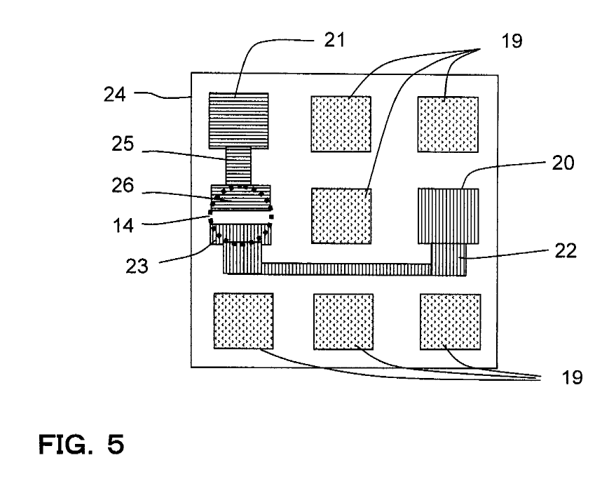

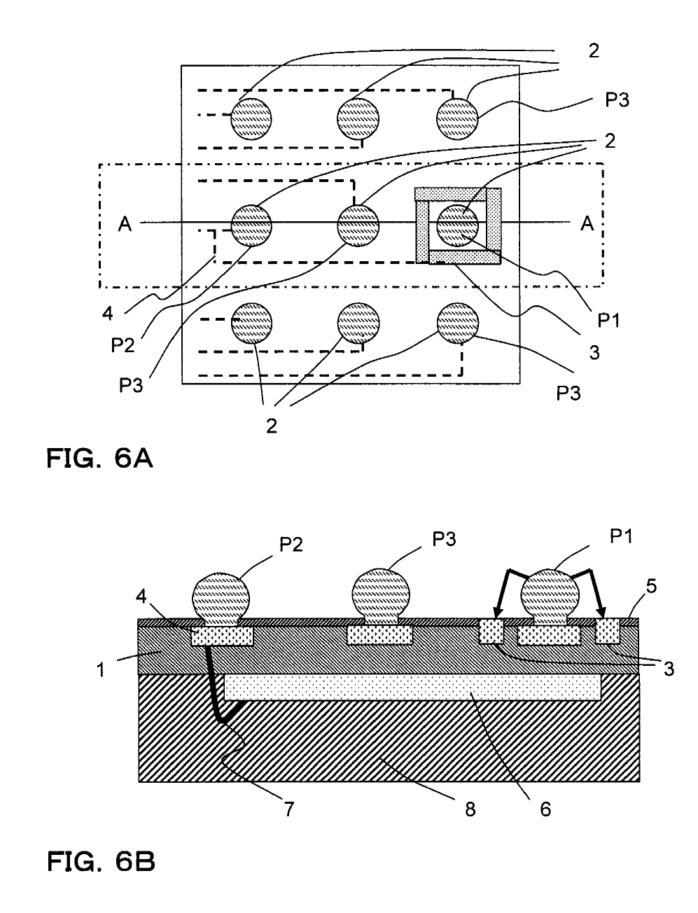

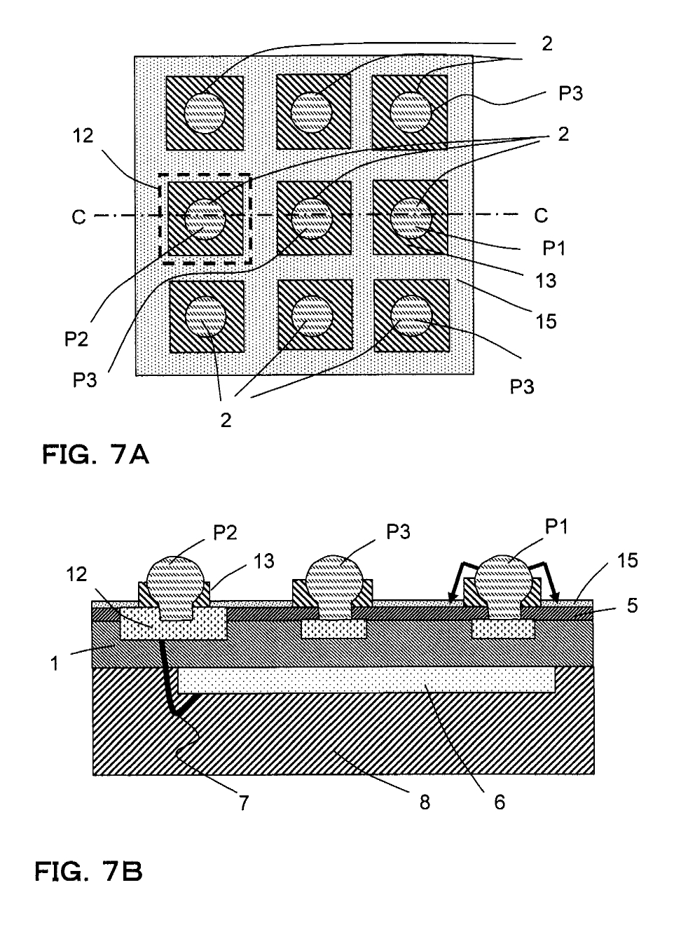

In a second exemplary embodiment, two ESD surge absorption wirings, which are separated from each other, are disposed to face the wiring of an NC pin P1. The two ESD surge absorption wirings are connected to a ground potential wiring and to a power supply potential wiring, respectively. The structure of a third wiring layer of a print substrate of a package of the second exemplary embodiment is different from that of the first exemplary embodiment. FIG. 5 shows a plan view of the pattern of the third wiring layer of the semiconductor package. In the embodiment, since the plan views of the respective patterns of an insulation film layer 5 and first and second wiring layers 13, 18, which constitute the print substrate 1, are the same as those of FIGS. 3A, 3B, and 4A in the first exemplary embodiment, the explanation thereof is omitted.

Referring to FIG. 5, an ESD surge absorption interface in a third wiring layer 24 is composed of ESD surge absorption wirings 23, 26 which are connected to wirings 20 and 24 through connection wirings 22, 25. Accordingly, the ESD surge absorption wiring 23 is connected to a ground potential wiring, whereas the ESD surge absorption wiring 26 is connected to a power supply potential wiring. These ESD surge absorption wirings 23, 26 are disposed in the lower semicircle and the upper semicircle of the circle of a through hole 14 of the second wiring layer 18 so that they do not come into contact with each other.

ESD noise applied to an NC pin P1 of the semiconductor package of the second exemplary embodiment will be explained. Suppose that the ESD noise applied to the NC pin P1 is electrostatically charged to a solder ball and a wiring 9. The ESD noise generates an aerial discharge to the ESD surge absorption wiring of the wiring layer 24 from the wiring 9 of the wiring layer 13 through the through hole 14 of the wiring layer 18. At the time, when the applied ESD noise has a positive polarity, the ESD noise is discharged to the ESD surge absorption wiring 23 of the wiring layer 24, thereby a surge being absorbed to the ground potential wiring. When the applied ESD noise has a negative polarity, the ESD noise is discharged to the ESD surge absorption wiring 26 of the wiring layer 24, thereby a surge being absorbed to the power supply potential wiring 26. The ground potential wiring and the power supply potential wiring can absorb the ESD noise because they are connected commonly in the semiconductor chip and have a large wiring capacity. Since the aerial discharge is generated first to the ESD surge absorption wiring, no aerial discharge is generated to adjacent input/output pins P3. Accordingly, the ESD noise can be absorbed like the first exemplary embodiment.

In the semiconductor package of the present invention, the wiring of the NC pin and the ESD noise absorption wiring are disposed to face to each other across a void having an internal D in the package. The void interval D is made shorter than the interval L between adjacent pins (solder balls). With this arrangement, the ESD noise applied to the NC pin is aerially discharged to the ESD noise absorption wiring. The ESD noise absorption wiring can be connected to the ground potential wiring and to the power supply potential wiring. Provision of the ESD noise absorption wiring can prevent transmission of a surge to input/output pins. Since the ESD noise absorption wiring is disposed in the print substrate, an exposed absorption wiring can be prevented from being short circuited with an adjacent pin though a solder adhered thereto when the solder balls are mounted. Further, since the ESD noise absorption wiring is disposed in the print substrate, it can be prevented from being subjected to corrosion, oxidation, and the like which are caused when it were disposed in air, thereby the ESD noise being securely absorbed.

Although the present invention has been specifically explained above based on the embodiments, the present invention is by no means limited to the above embodiments and can be variously modified within the scope which does not depart from the gist thereof, and it is needless to say that these modifications are also included in the present invention.

What is claimed is:

1. A semiconductor package having a print substrate comprising a plurality of wiring layers comprising:
a void formed to an intermediate wiring layer which is one of the plurality of wiring layers; and a wiring of a non connect pin and a noise absorption wiring are disposed to face to each other across the void.

2. The semiconductor package according to claim 1, wherein a void interval (D) between the wiring of the non connect pin and the noise absorption wiring, which face to each other, is shorter than an interval (L) between pins to be connected to the outside.

3. The semiconductor package according to claim 2, wherein the noise absorption wiring is connected to any of the ground potential wiring or the power supply potential wiring.

4. The semiconductor package according to claim 3, wherein the non connect pin is not connected a semiconductor chip and is placed in an open state.

5. The semiconductor package according to claim 4, wherein the pins to be connected to the outside are formed of solder balls.

6. A semiconductor device having a semiconductor chip, comprising:
a semiconductor package comprising a print substrate including a plurality of wiring layers including an intermediate wiring layer, a void disposed to the intermediate wiring layer, and an wiring of a non connect pin and a noise absorption wiring disposed to face to each other across the void;
solder balls mounted on a first side surface of the print substrate; and
the semiconductor chip mounted on a second side surface facing the first side surface.

7. The semiconductor device according to claim 6, wherein a void interval (D) between the wiring of the non connect pin and the noise absorption wiring, which face to each other, is shorter than an interval (L) between the solder balls.

8. The semiconductor device according to claim 7, wherein the noise absorption wiring is connected to any of the ground potential wiring or the power supply potential wiring.

9. A semiconductor package having a print substrate comprising a plurality of wiring layers, comprising:
a wiring for connect pins extending internally across the plurality of wiring layers from one surface of the print substrate;
a wiring for a non connect pin insulated in the thickness direction of the plurality of wiring layers by a void formed to an intermediate wiring layer as one of the plurality of wiring layers; and
a surge absorption wiring facing the wiring for the non connect pin across the void.

10. The semiconductor package according to claim 9, wherein the interval of the void between the wiring for the non connect pin and the surge absorption wiring is set smaller than the interval between a non connect pin to be disposed and a connect pin adjacent to the connect pin.

11. The semiconductor package according to claim 9, wherein the surge absorption wiring is connected to at least one of the ground potential wiring or the power supply potential wiring.

12. The semiconductor package according to claim 9, wherein the surge absorption wiring comprises a first surge absorption wiring and a second surge absorption wiring which are insulated from each other and face the wiring of the connect pin across the void together.

13. A semiconductor device comprising:
a semiconductor package including a print substrate comprising a plurality of wiring layers, wiring for connect pins extending internally across the plurality of wiring layers from one surface of the print substrate, a wiring for a non connect pin insulated in the thickness direction of the plurality of wiring layers by a void formed to an intermediate wiring layer as one of the plurality of wiring layers, and a surge absorption wiring facing the wiring for the non connect pin across the void; and
a plurality of pins including the connect pin and the non connect pin disposed to one surface of the print substrate and a semiconductor chip mounted on the other surface,
wherein the connect pin is connected to the semiconductor chip; and
the surge absorption wiring is connected to at least one of the ground potential wiring or the power supply potential wiring.

14. The semiconductor device according to claim 13, wherein an interval of the void between the wiring of the non connect pin and the surge absorption wiring is smaller than an interval between the non connect pin and the connect pins adjacent to the non connect pin.

15. The semiconductor device according to claim 13, wherein the surge absorption wiring comprises a first surge absorption wiring and a second surge absorption wiring which are insulated from each other and face the wiring of the non connect pin across the void together.

16. The semiconductor device according to claim 15, wherein the first surge absorption wiring is connected to a ground potential wiring, and the second surge absorption wiring is connected to a power supply potential wiring.

17. The semiconductor device according to claim 13, wherein the pins are formed of solder balls.
